(19) United States
(12) Patent Application Publication
(10) Pub. No.: US 2006/0249079 A1
(43) Pub. Date: Nov. 9, 2006

(54) WAFER HEATER AND WAFER CHUCK INCLUDING THE SAME

(76) Inventors: Ping-Hua Yao, N/A (SG); Hsin-Hung Chen, N/A (SG)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,338

(22) Filed: May 9, 2005

(51) Int. Cl. C23F 1/00; C23C 16/00

(52) U.S. Cl. 118/725; 156/345.52

(57) ABSTRACT

A wafer heater is provided, including a body also serving as a heat source, a ceramic ring on the body, and a buffer ring on the body. The buffer ring contacts with the ceramic ring, and has a top surface higher than that of the ceramic ring so that a wafer can be placed on the top surface of the buffer ring without contacting the ceramic ring. The thermal conductivity coefficient of the buffer ring is smaller than that of the ceramic ring. The product of thermal conductivity coefficient and top surface area of the buffer ring is also smaller than that of the ceramic ring.

### BACKGROUND OF THE INVENTION

1. Field of the Invention

The present invention relates to equipment of semiconductor processes. More particularly, the present invention relates to a wafer heater that causes less thermal stress in the wafer, and a wafer chuck including the wafer heater to have heating capability.

2. Description of the Related Art

In a semiconductor process requiring higher temperature, a wafer is usually heated by a heater disposed on the wafer chuck that holds the wafer in the process. A conventional wafer chuck with heating capability has a ceramic ring and an air-drawing means under the opening of the ceramic ring. The ceramic ring is thermally coupled with a heat source, and the wafer to be treated is placed on the ceramic ring and fixed thereon through suction of the air-drawing means. The heat from the heat source is conducted to the wafer via the ceramic ring, so that the wafer can be heated to desired temperature. The ceramic ring is used in the wafer chuck mainly for its superior hardness and heat-resistance.

However, since the ceramic ring does not contact with the whole lower surface of the wafer, temperature difference inevitably occurs on the wafer. For current use, the ceramic ring has relatively higher thermal conductivity, such that the temperature difference and the resulting thermal stress are frequently overly large to cause wafer breakage.

### SUMMARY OF THE INVENTION

In view of the foregoing, this invention provides a wafer heater that causes less thermal stress and thereby effectively prevents wafer breakage.

This invention also provides a wafer chuck with heating capability that includes the wafer heater of this invention.

The wafer heater of this invention includes a body also serving as a heat source, a ceramic ring on the body and a buffer ring on the body. The ceramic ring is thermally coupled with the body as a heat source. The buffer ring contacts with the ceramic ring, and has a top surface higher than the top surface of the ceramic ring so that a wafer can be placed on the top surface of the buffer ring without contacting the ceramic ring. The thermal conductivity coefficient (μ₁) of the buffer ring is smaller than that (μ₂) of the ceramic ring. The product (p₁=μ₁×A₁) of the thermal conductivity coefficient (μ₁) and the top surface area (A₁) of the buffer ring is also smaller than the product (p₂=μ₂×A₂) of the thermal conductivity coefficient (μ₂) and the top surface area (A₂) of the ceramic ring.

To understand the effect of this invention, the following equation of thermal conduction is discussed:
Q=μ×A×ΔT (1)
wherein Q is the thermal conduction rate of a thermal conductor, μ is the thermal conductivity coefficient of the same, A is the contact area (or the top surface area) of the same, and ΔT is the temperature difference. According to equation (1), decreasing the product of μ and A will decreases the thermal conduction rate “Q” of the thermal conductor. Since the thermal conductivity coefficient of the buffer ring and the product of thermal conductivity coefficient and top surface area of the same are smaller than those of the ceramic ring, the thermal conduction from the body of the wafer heater to the wafer placed on the buffer ring is slowed down. Therefore, the temperature difference on the wafer is smaller as compared with the prior art, so that less thermal stress is generated lowering the possibility of wafer breakage.

The wafer chuck of this invention is based on the above wafer heater of this invention, wherein an air-drawing means is further disposed in the region of the body surrounded by the ceramic ring, i.e., the region under the opening of the ceramic ring. When a wafer is placed on the top surface of the buffer ring, vacuum can be generated, by the air-drawing means, in the space enclosed by the body, the ceramic ring, the buffer ring and the wafer, so as to hold the wafer tightly on the wafer chuck.

It is to be understood that both the foregoing general description and the following detailed description are exemplary, and are intended to provide further explanation of the invention as claimed.

### BRIEF DESCRIPTION OF THE DRAWINGS

FIG. 1A illustrates a top view of a wafer chuck with heating capability according to a preferred embodiment of this invention, and FIG. 1B illustrates a cross-sectional view of the same along line I-I′.

### DESCRIPTION OF THE PREFERRED EMBODIMENTS

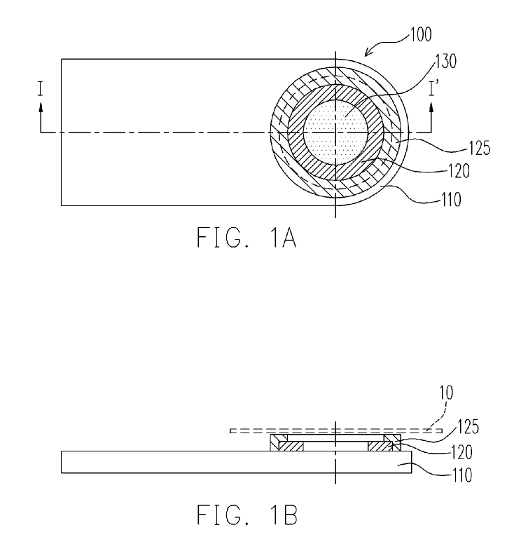

Referring to FIG. 1A, the wafer chuck 100 according to the preferred embodiment of this invention includes a body 110 also serving as a heat source, a ceramic ring 120, a buffer ring 125 and an air-drawing means 130. The body may be made from an electrically non-conductive material having superior hardness and heat-resistance, such as, a ceramic material.

The ceramic ring 120 and the buffer ring 125 both are disposed on the end of the body 110 contacting with each other. The air-drawing means 130 is disposed in the region of the body 110 surrounded by the ceramic ring 120, i.e., the region of the body 110 exposed in the opening of the ceramic ring 120. Such a wafer chuck 100 is suitably used in a plasma photoresist ashing apparatus.

More specifically, as shown in FIGS. 1A and 1B, the buffer ring 125 is disposed at the outer periphery of the ceramic ring 120, and has an inner peripheral surface contacting with the outer peripheral surface of the ceramic ring 120. The top surface of the buffer ring 125 is higher than that of the ceramic ring 120, so that a wafer 10 can be placed on the top surface of the buffer ring 125 without contacting with the ceramic ring 120. Moreover, the buffer ring 125 may further extend inward to contact with the top surface of the ceramic ring 120, as shown in FIG. 1B. In addition, since a wafer 10 has a circular shape, the ceramic ring 120 and the buffer ring 125 preferably has a circular shape so that the heat conduction on the wafer 10 is symmetric.

The thermal conductivity coefficient (μ₁) of the buffer ring 125 is smaller than that (μ₂) of the ceramic ring 120 (μ₁<μ₂). Such a buffer ring 125 can be made from a heat-resistant polymer. For use in plasma photoresist ashing processes that are usually conducted under relatively lower temperature, quite a lot polymer materials can meet the requirement of heat resistance to be used as the material of the buffer ring 125.

Moreover, the product (p₁=μ₁×A₁) of the thermal conductivity coefficient (μ₁) and the top surface area (A₁) of the buffer ring 125 is smaller than the product (p₂=μ₂×A₂) of the thermal conductivity coefficient (μ₂) and the top surface area (A₂) of the ceramic ring 120 (P₁<P₂). In the above description, the top surface area of the buffer ring 125 is defined as the area of the top surface of the buffer ring 125 that directly contacts with the wafer 10. Similarly, the top surface area of the ceramic ring 120 is defined as the area of the top surface of the ceramic ring 120 that would directly contact with the wafer 10 if the buffer ring 125 were absent as in the prior art. To meet this requirement of P₁<P₂, it is feasible to set the top surface area (A₁) of the buffer ring 125 smaller than that (A₂) of the ceramic ring 120 (A₁<A₂).

In addition, the air-drawing means 130 in the region of the body 110 surrounded by the ceramic ring 120 may include many holes formed on the surface of the region, wherein the holes are connected to an air pump (not shown) via, for example, an air channel (not shown) within the body 110. When the wafer 10 is placed on the top surface of the buffer ring 125 and the air-drawing means 130 is turned on by switching the air pump on, the wafer 10 can be held tightly on the wafer chuck 100 through suction of the air-drawing means 130.

Since the thermal conductivity coefficient of the buffer ring and the product of thermal conductivity coefficient and top surface area of the same are smaller than those of the ceramic ring, the thermal conduction from the body of the wafer chuck to the wafer is slowed down. Therefore, the temperature difference on the wafer is smaller as compared with the prior art, so that less thermal stress is generated lowering the possibility of wafer breakage.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A wafer heater, comprising:
a body also serving as a heat source;
a ceramic ring on the body; and
a buffer ring on the body, contacting with the ceramic ring and having a top surface higher than a top surface of the ceramic ring so that a wafer can be placed on the top surface of the buffer ring without contacting the ceramic ring,
wherein a thermal conductivity coefficient (μ₁) of the buffer ring is smaller than a thermal conductivity coefficient (μ₂) of the ceramic ring, and a product (p₁=μ₁×A₁) of the thermal conductivity coefficient and a top surface area (A₁) of the buffer ring is smaller than a product (p₂=μ₂×A₂) of the thermal conductivity coefficient and a top surface area (A₂) of the ceramic ring.

2. The wafer heater of claim 1, wherein the top surface area (A₁) of the buffer ring is smaller than the top surface area (A₂) of the ceramic ring.

3. The wafer heater of claim 1, wherein the buffer ring is disposed at outer periphery of the ceramic ring and has an inner peripheral surface contacting with an outer peripheral surface of the ceramic ring.

4. The wafer heater of claim 3, wherein the buffer ring further extends inward to contact with the top surface of the ceramic ring.

5. The wafer heater of claim 1, wherein each of the ceramic ring and the buffer ring is shaped as a circular ring.

6. The wafer heater of claim 1, wherein the buffer ring comprises a heat-resistant polymer.

7. A wafer chuck with heating capability, comprising:
a body also serving as a heat source;
a ceramic ring on the body;
a air-drawing means in a region of the body surrounded by the ceramic ring; and
a buffer ring on the body, contacting with the ceramic ring and having a top surface higher than a top surface of the ceramic ring so that a wafer can be placed on the top surface of the buffer ring without contacting the ceramic ring,
wherein a thermal conductivity coefficient (μ₁) of the buffer ring is smaller than a thermal conductivity coefficient (μ₂) of the ceramic ring, and a product (p₁=μ₁×A₁) of the thermal conductivity coefficient and a top surface area (A₁) of the buffer ring is smaller than a product (p₂=μ₂×A₂) of the thermal conductivity coefficient and a top surface area (A₂) of the ceramic ring.

8. The wafer chuck of claim 7, wherein the top surface area (A₁) of the buffer ring is smaller than the top surface area (A₂) of the ceramic ring.

9. The wafer chuck of claim 7, wherein the buffer ring is disposed at outer periphery of the ceramic ring and has an inner peripheral surface contacting with an outer peripheral surface of the ceramic ring.

10. The wafer chuck of claim 9, wherein the buffer ring further extends inward to contact with the top surface of the ceramic ring.

11. The wafer chuck of claim 7, wherein each of the ceramic ring and the buffer ring is shaped as a circular ring.

12. The wafer chuck of claim 7, wherein the buffer ring comprises a heat-resistant polymer.

13. The wafer chuck of claim 7, which is a part of a plasma photoresist ashing apparatus.
